(19) United States
(12) Patent Application Publication
(10) Pub. No.: US 2003/0070265 A1
(43) Pub. Date: Apr. 17, 2003

(54) Clip for holding a heat sink on an enclosure surrounding a CPU

(76) Inventor: Jen-Cheng Lin, Chung-Ho City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/974,866

(22) Filed: Oct. 12, 2001

(51) Int. Cl. H05K 7/20

(52) U.S. Cl. 24/458

(57) ABSTRACT

A clip for holding a heat sink on an enclosure which surrounds a Pentium IV™ CPU and which has a plurality of holes defined therein. The clip includes a U-shaped resiliently flexible body having a curved bottom and a pair of butt ends. And each of the butt ends has an appendage formed with a barb to be snapped into corresponding one of the holes in the enclosure.

### BACKGROUND OF THE INVENTION

1. Field of the Invention

The present invention relates to a clip for holding a heat sink on a CPU and, more particularly, to a clip for holding a heat sink on an enclosure surrounding a CPU, especially a Pentium IV™ CPU.

2. Description of Related Art

A heat sink is required in a computer to remove or dissipate heat generated by a CPU(Central Processing Unit) during its operation. The heat sink is generally held directly on the CPU by a pair of clips.

Intel Corp.™ now produces Pentium IV™ CPU's, a new model incorporated with a standard enclosure, which prevents every type of conventional clip from holding the heat sink on the new CPU.

Therefore, it is an objective of the invention to provide a clip to mitigate and/or obviate the aforementioned problem.

### SUMMARY OF THE INVENTION

The object of the present invention is to provide a clip for holding a heat sink on an enclosure surrounding a CPU, especially a Pentium IV™ CPU.

Other objects, advantages and novel features of the invention will become more apparent from the following detailed description when taken in conjunction with the accompanying drawings.

### BRIEF DESCRIPTION OF THE DRAWINGS

FIG. 1 is a perspective view of a pair of clips, in accordance with the present invention, for holding a heat sink on an enclosure surrounding a Pentium VI™ CPU;

FIG. 2 is a view showing the clips, heat sink and enclosure separately;

FIG. 3 is a front view showing one of the clips hitched to the enclosure at its one side;

FIG. 4 is a front view showing the clip hitched to the enclosure at its both sides and holding the heat sink on the enclosure; and

FIG. 4 is a side view showing the clip hitched to the enclosure at its both sides and holding the heat sink on the enclosure.

### DETAILED DESCRIPTION OF THE PREFERRED EMBODIMENT

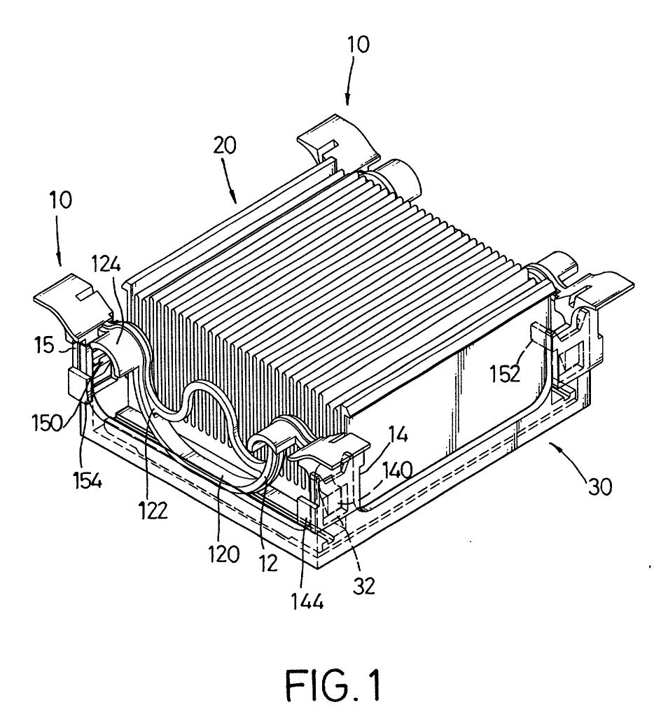

Referring to FIG. 1, there is shown a preferred embodiment of a pair of clips (10) in accordance with the present invention for holding a heat sink (20) on an enclosure (30) surrounding a Pentium IV™ CPU (not shown).

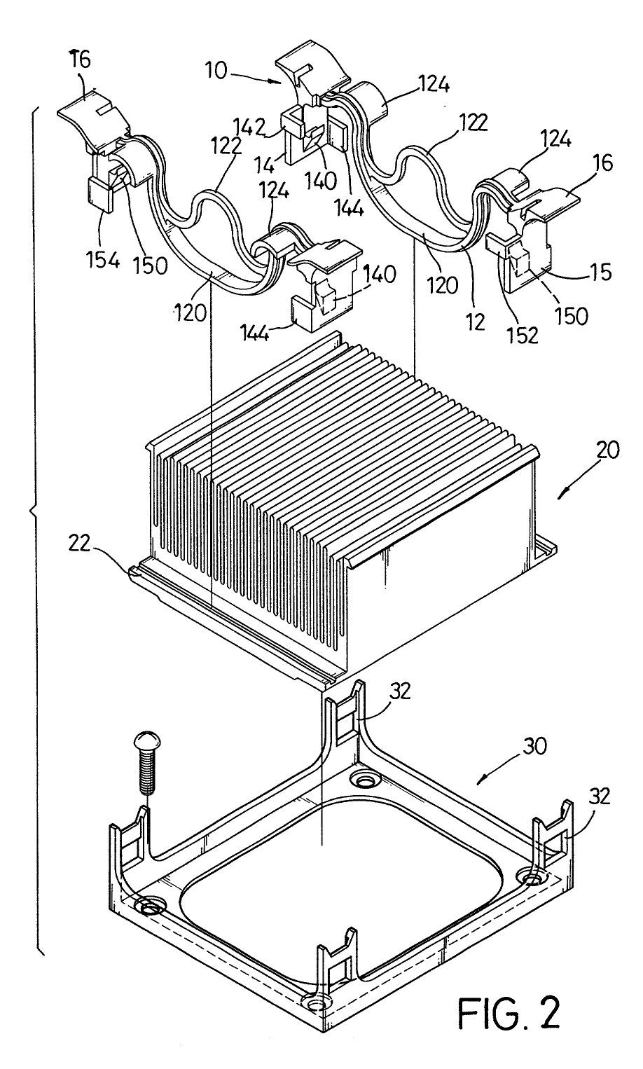

Referring to FIG. 2, the enclosure (30), incorporated with the Pentium IV™ CPU, is formed with holes (32) as known in the art. The heat sink (20) here has a plurality of parallel fins (not numbered) and particularly a pair of opposed lower flanges (22) perpendicular to the fins.

Each of the clips (10) includes a U-shaped, resiliently flexible body (12) having a curved bottom (120) and a pair of butt ends (16), with each butt end (16) having an appendage (14,15) formed with a barb (140,150) to be snapped into corresponding one of the holes (32) of the enclosure (30).

The U-shaped body (12) preferably has an arched upper rib (122) joined thereto to strengthen the body (12), and a pair of reinforcements (124) formed thereon adjacent to the butt ends (16). It is more preferable that each appendage (14,15) has an inner lateral guard (142,152) and an outer lateral guard (144,154) extending therefrom.

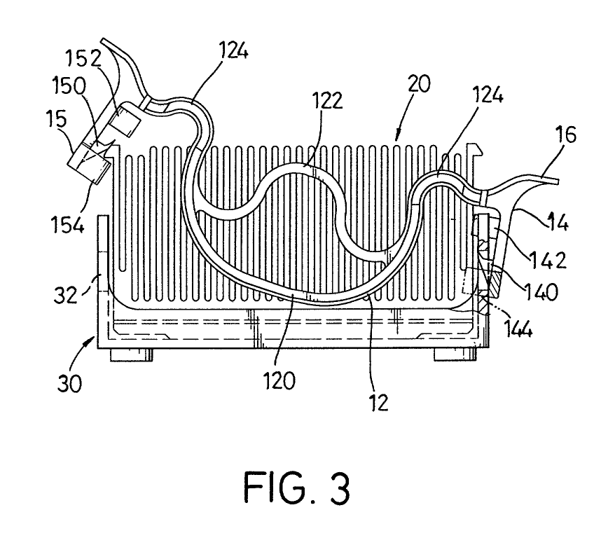

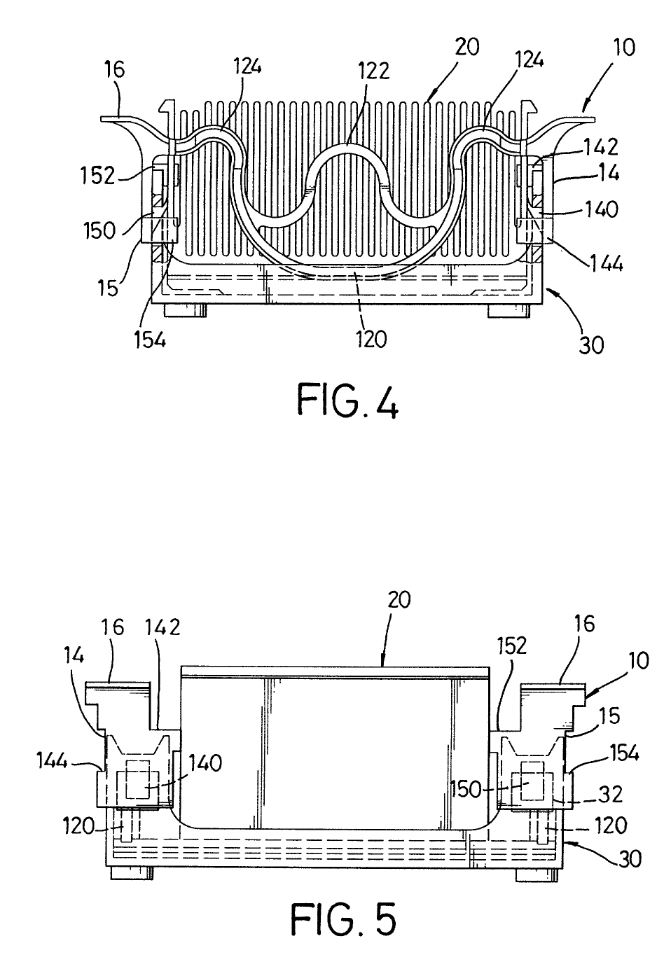

Referring to FIG. 3, the heat sink (20) is positioned on the CPU by placing it in the enclosure (30). Either of the clips (10) can be then applied to the enclosure (30), with one barb (14) engaging with one hole (32) of the enclosure (30), before the opposite butt end (16) is pressed down so that the other barb (15) is snapped into the opposed hole (32), as shown in FIG. 4.

The other clip (10) can be applied to the enclosure (30) in the same way as just mentioned above.

Referring to 4, the heat sink (20) is now pressed against the CPU by the curved bottoms (120) of the clips (10), which are deformed and exert pressure upon the opposed lower flanges (22) of the heat sink (20).

The heat sink (20) is positioned properly on the CPU additionally by the inner lateral guards (142,152) which now abut against the heat sink (20) while the outer lateral guards (144,154) abut the enclosure (30), as clearly shown in FIGS. 4 and 5.

From the above description, it is noted that the invention has the advantage of holding the heat sink (20) on the enclosure (30) surrounding the Pentium IV™ CPU.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A clip (10) for holding a heat sink (20) on an enclosure (30) surrounding a Central Processing Unit, said enclosure (30) having a plurality of holes (32) defined therein, said clip (10) comprising a U-shaped resiliently flexible body (12) having a curved bottom (120) and a pair of butt ends (16), and each of said butt ends (16) having an appendage (14,15) formed with a barb (140,150) to be snapped into corresponding one of said holes (32) in said enclosure (30).

2. The clip (10) as claimed in claim 1, wherein said U-shaped body (12) has an arched rib (122) joined thereto.

3. The clip (10) as claimed in claim 1, wherein said U-shaped body (12) has a pair of reinforcements (124) formed adjacent to said butt ends (16).

4. The clip (10) as claimed in claim 1, wherein said appendage (14,15) has an inner lateral guard (142,152) to abut against the heat sink (20).

5. The clip (10) as claimed in claim 4, wherein said appendage (14,15) further has an outer lateral guard (144,154) to abut against the enclosure (30).
